(19) United States
(12) Patent Application Publication
(10) Pub. No.: US 2022/0283199 A1
(43) Pub. Date: Sep. 8, 2022

(54) NITRIDE SEMICONDUCTOR, WAFER, SEMICONDUCTOR DEVICE, AND METHOD FOR MANUFACTURING THE NITRIDE SEMICONDUCTOR

(71) Applicant: KABUSHIKI KAISHA TOSHIBA, Tokyo (JP)

(72) Inventors: Hajime NAGO, Yokohama (JP); Jumpei TAJIMA, Mitaka (JP); Toshiki HIKOSAKA, Kawasaki (JP)

(73) Assignee: KABUSHIKI KAISHA TOSHIBA, Tokyo (JP)

(21) Appl. No.: 17/400,510

(22) Filed: Aug. 12, 2021

(30) Foreign Application Priority Data
Mar. 3, 2021 (JP) 2021-033227

(51) Int. Cl. G01Q 60/24; H01J 37/244; H01L 29/20

(52) U.S. Cl. CPC G01Q 60/24; H01J 37/244; H01L 29/2003; H01J 2237/2802

(57) ABSTRACT

According to one embodiment, a nitride semiconductor includes a nitride member including a first nitride region, a second nitride region, and a third nitride region. The second nitride region is between the first nitride region and the third nitride region in a first direction. A HAADF-STEM (High Angle Annular Dark-Field Scanning Transmission Electron Microscopy) image of the nitride member includes a plurality of bright points and a dark area between the bright points. The dark area is darker than the bright points. A third brightness of the dark area in a third image region corresponding to the third nitride region is lower than a first brightness of the dark area in a first image region corresponding to the first nitride region. A second brightness of the dark area in a second image region corresponding to the second nitride region is lower than the third brightness.

### CROSS-REFERENCE TO RELATED APPLICATIONS

This application is based upon and claims the benefit of priority from Japanese Patent Application No. 2021-033227, filed on Mar. 3, 2021; the entire contents of which are incorporated herein by reference.

### FIELD

Embodiments described herein relate generally to a nitride semiconductor, a wafer, a semiconductor device, and a method for manufacturing the nitride semiconductor device.

### BACKGROUND

For example, there is a semiconductor device using a nitride semiconductor such as GaN. It is desired to improve the characteristics of semiconductor devices.

### BRIEF DESCRIPTION OF THE DRAWINGS

FIG. 1 is a schematic cross-sectional view illustrating a nitride semiconductor according to a first embodiment;

FIGS. 2A and 2B are an Atomic Force Microscope image illustrating the nitride semiconductor;

FIG. 3 is a graph view illustrating characteristics of the nitride semiconductor;

FIGS. 4A to 4C are graph views illustrating characteristics of a semiconductor device;

FIGS. 5A to 5C are a HAADF-STEM image of the nitride semiconductor;

FIGS. 6A and 6B are graph views illustrating distributions of brightness in the HAADF-STEM image of the nitride semiconductor;

FIG. 7 is a graph view illustrating characteristics of the semiconductor device;

FIG. 8 is a schematic cross-sectional view illustrating a semiconductor device according to a second embodiment; and

FIG. 9 is a flow chart illustrating a method for manufacturing the nitride semiconductor according to a third embodiment.

### DETAILED DESCRIPTION

According to one embodiment, a nitride semiconductor includes a nitride member including a first nitride region, a second nitride region, and a third nitride region. The second nitride region is between the first nitride region and the third nitride region in a first direction. The first nitride region includes Alₓ₁Ga₁₋ₓ₁N (0≤x1<1). The second nitride region includes Alₓ₂Ga₁₋ₓ₂N (0<x2≤1, x1<x2). The third nitride region includes Alₓ₃In₁₋ₓ₃N (0<x3<1, x3<x2) or Al_{y3}Ga_{1-y3}N (0<y3<1, x1<y3<x2). A HAADF-STEM (High Angle Annular Dark-Field Scanning Transmission Electron Microscopy) image of the nitride member includes a plurality of bright points and a dark area between the bright points. The dark area is darker than the bright points. A third brightness of the dark area in a third image region corresponding to the third nitride region is lower than a first brightness of the dark area in a first image region corresponding to the first nitride region. A second brightness of the dark area in a second image region corresponding to the second nitride region is lower than the third brightness.

According to one embodiment, a wafer includes the nitride semiconductor described above and a substrate. The second nitride region is between the substrate and the third nitride region. The first nitride region is between the substrate and the second nitride region.

According to one embodiment, a semiconductor device further includes the nitride semiconductor described above, a first electrode, a second electrode, a third electrode, and an insulating member. A direction from the first electrode toward the second electrode is along a second direction crossing the first direction. A position in the second direction of the third electrode is between a position in the second direction of the first electrode and a position in the second direction of the second electrode. The first nitride region includes a first partial region, a second partial region, a third partial region, a fourth partial region, and a fifth partial region. A direction from the first partial region toward the first electrode is along the first direction. A direction from the second partial region toward the second electrode is along the first direction. The third partial region is between the first partial region and the second partial region in the second direction, and a direction from the third partial region toward the third electrode is along the first direction. The fourth partial region is between the first partial region and the third partial region in the second direction. The fifth partial region is between the third partial region and the second partial region in the second direction. The third nitride region includes a sixth partial region and a seventh partial region. A direction from the fourth partial region toward the sixth partial region is along the first direction. A direction from the fifth partial region toward the seventh partial region is along the first direction. The insulating member includes a first insulating region provided between the third partial region and the third electrode in the first direction.

According to one embodiment, a method for manufacturing a nitride semiconductor is disclosed. The method can include forming a second nitride region including Alₓ₂Ga₁₋ₓ₂N (0<x2≤1, x1<x2) on a first nitride region including Alₓ₁Ga₁₋ₓ₁N (0≤x1<1). The method can include forming a third nitride region including Alₓ₃In₁₋ₓ₃N (0<x3<1, x3<x2) or Al_{y3}Ga_{1-y3}N (0<y3<1, x1<y3<x2) on the second nitride region. The forming the second nitride region includes forming the second nitride region by using a processing gas including a first gas including Al, a second gas including ammonia, and a third gas including hydrogen and nitrogen. A volume ratio of the nitrogen in the third gas is not less than 20% and not more than 50%.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

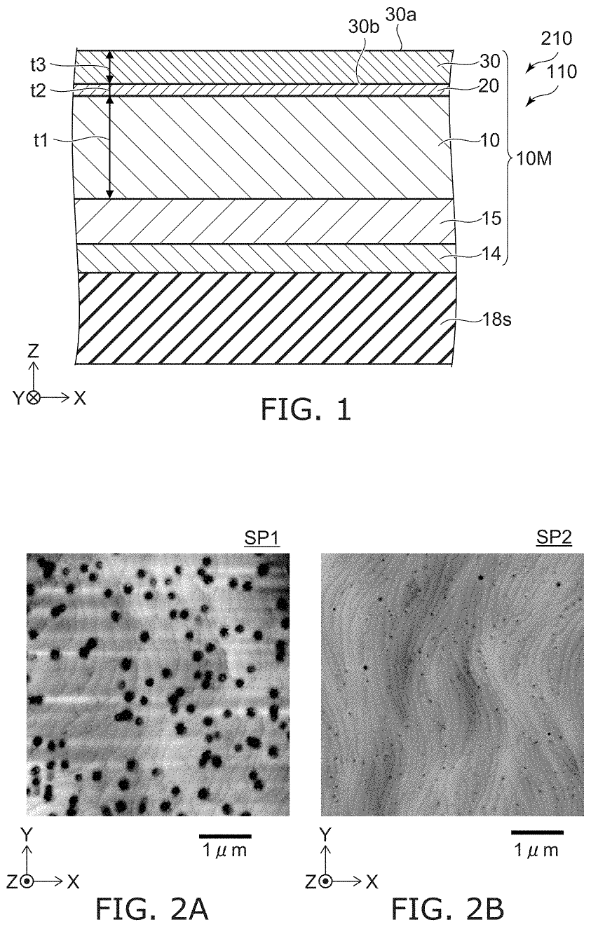

FIG. 1 is a schematic cross-sectional view illustrating a nitride semiconductor according to a first embodiment.

As shown in FIG. 1, a nitride semiconductor 110 according to the embodiment includes a nitride member 10M. The nitride member 10M includes a first nitride region 10, a second nitride region 20, and a third nitride region 30. The second nitride region 20 is between the first nitride region 10 and the third nitride region 30 in a first direction.

The first direction is taken as a Z-axis direction. One direction perpendicular to the Z-axis direction is taken as an X-axis direction. The direction perpendicular to the Z-axis direction and the X-axis direction is taken as a Y-axis direction. Each of the first nitride region 10, the second nitride region 20, and the third nitride region 30 is a layer extending along the X-Y plane.

The first nitride region 10 includes Alₓ₁Ga₁₋ₓ₁N (0≤x1<1). The first nitride region 10 is, for example, GaN. The composition ratio of Al in the first nitride region 10 is, for example, not less than 0 and not more than 0.1.

The second nitride region 20 includes Alₓ₂Ga₁₋ₓ₂N (0<x2≤1, x1<x2). The second nitride region 20 is, for example, AlN. The composition ratio of Al in the second nitride region 20 is, for example, not less than 0.9 and not more than 1.

The third nitride region 30 includes Alₓ₃In₁₋ₓ₃N (0<x3<1, x3<x2) or Al_{y3}Ga_{1-y3}N (0<y3<1, x1<y3<x2). The third nitride region 30 includes, for example, AlInN. When the third nitride region 30 includes Alₓ₃In₁₋ₓ₃N, the composition ratio of In in the third nitride region 30 is not less than 0.15 and not more than 0.25. The third nitride region 30 may include, for example, AlGaN. When the third nitride region 30 includes Al_{y3}Ga_{1-y3}N, the composition ratio of Al is not less than 0.1 and not more than 0.3. In the following, an example in which the third nitride region 30 includes Alₓ₃In₁₋ₓ₃N (AlInN) will be described.

For example, the thickness t1 of the first nitride region 10 is, for example, not less than 0.5 μm and not more than 3 μm. The thickness t2 of the second nitride region 20 is, for example, not less than 0.5 nm and not more than 1.5 nm. The thickness t3 of the third nitride region 30 is, for example, not less than 5 nm and not more than 20 nm. These thicknesses are lengths along the first direction (Z-axis direction).

As shown in FIG. 1, the nitride semiconductor 110 may be included in a wafer 210. The wafer 210 includes, for example, the above-mentioned nitride semiconductor 110 and a substrate 18s. There is the second nitride region 20 between the substrate 18s and the third nitride region 30. There is the first nitride region 10 between the substrate 18s and the second nitride region 20. The substrate 18s includes, for example, silicon. The substrate 18s is, for example, a silicon substrate.

As shown in FIG. 1, the nitride member 10M may include a fourth nitride region 14 and a fifth nitride region 15. There is the fifth nitride region 15 between the substrate 18s and the first nitride region 10. There is the fourth nitride region 14 between the substrate 18s and the fifth nitride region 15. The fourth nitride region 14 includes, for example, AlN. The fourth nitride region 14 functions as, for example, a buffer layer. The fifth nitride region 15 includes AlGaN. The fifth nitride region 15 may include multiple regions having different Al composition ratios along the Z-axis direction. The fifth nitride region 15, for example, alleviates strain.

The surface of the third nitride region 30 is preferably flat. As a result, for example, in a semiconductor device using the nitride semiconductor 110, stable characteristics can be easily obtained. For example, high reliability can be obtained.

As shown in FIG. 1, the third nitride region 30 includes a first surface 30a and a second surface 30b. The second surface 30b faces the second nitride region 20. In the first direction (Z-axis direction), the second surface 30b is between the second nitride region 20 and the first surface 30a. The first surface 30a corresponds to the surface of the third nitride region 30. The first surface 30a is preferably flat.

As will be described later, the nitride member 10M can be formed by growing a nitride crystal on the substrate 18s. For example, the second nitride region 20 is formed on the first nitride region 10. The third nitride region 30 is formed on the second nitride region 20.

It was found that in the formation of the second nitride region 20 (for example, AlN), the characteristics of the second nitride region 20 and the third nitride region 30 are changed by the carrier gas. For example, the unevenness of the surface (first surface 30a) of the third nitride region 30 changes depending on the component of the carrier gas. Hereinafter, an example of the result of the experiment conducted by the inventor of the application will be described.

In the experiment, the nitride semiconductor sample was obtained by forming the second nitride region 20 on the first nitride region 10 and forming the third nitride region 30 on the second nitride region 20. In the sample, the first nitride region 10 is GaN. The second nitride region 20 is AlN. The third nitride region 30 is AlInN. The composition ratio of In in the third nitride region 30 is 0.2. The sample is prepared as follows.

The substrate 18s (silicon substrate) is introduced into a reaction furnace and heated to remove the oxide film on the surface. After that, the fourth nitride region 14 is formed on the substrate 18s. In the formation of the fourth nitride region 14, a carrier gas of hydrogen, a gas including TMAI (trimethylaluminum), and an ammonia gas are supplied.

The fifth nitride region 15 is formed on the fourth nitride region 14. In the formation of the fifth nitride region 15, a carrier gas of hydrogen, a gas including TMAI and TMGa (trimethylgallium), and an ammonia gas are supplied. By changing the ratio of TMAI and TMGa, regions having different Al composition ratios are formed.

The first nitride region 10 is formed on the fifth nitride region 15. In the formation of the first nitride region 10, a carrier gas of hydrogen, a gas including TMGa, and an ammonia gas are supplied. The thickness t1 of the first nitride region 10 is 2 μm.

The second nitride region 20 is formed on the first nitride region 10. In the experimental sample, the ratio of hydrogen and nitrogen included in the carrier gas is changed in the formation of the second nitride region 20. Such a carrier gas, a gas including TMAI, and an ammonia gas are supplied to form the second nitride region 20. The thickness t2 of the second nitride region 20 is 1 nm. The second nitride region 20 is AlN.

The third nitride region 30 is formed on the second nitride region 20. In the formation of the third nitride region 30, the carrier gas includes nitrogen and is substantially free of hydrogen. Such a carrier gas, a gas including TMAI and TMIn (trimethylindium), and an ammonia gas are supplied to form the third nitride region 30. The third nitride region 30 is AlInN. The temperature at which the third nitride region 30 is formed is lower than the temperature at which the first nitride region 10 and the second nitride region 20 are formed. As a result, the third nitride region 30 having high quality can be obtained.

FIGS. 2A and 2B are Atomic Force Microscope images illustrating a nitride semiconductor.

These figures are Atomic Force Microscope (AFM) images of the surface (first surface 30a) of the third nitride region 30. FIG. 2A corresponds to the first sample SP1. In the first sample SP1, the carrier gas in the formation of the second nitride region 20 is hydrogen. FIG. 2B corresponds to the second sample SP2. In the second sample SP2, the ratio (volume ratio) of nitrogen in the carrier gas in the formation of the second nitride region 20 is 33%.

As shown in FIG. 2A, in the first sample SP1 in which the carrier gas in the formation of the second nitride region 20 is hydrogen, in the AFM image of the surface (first surface 30a) of the third nitride region 30, multiple dark spots are observed. On the other hand, as shown in FIG. 2B, in the second sample SP2 in which the ratio of nitrogen included in the carrier gas in the formation of the second nitride region 20 is 33%, there are very few dark spots in AFM image of the surface (first surface 30a) of the third nitride region 30.

By observing the surface of the sample, it was found that the dark spots illustrated in FIG. 2A correspond to recesses formed on the surface (first surface 30a) of the third nitride region 30.

Even if the conditions for forming the third nitride region 30 are the same, the unevenness of the surface (first surface 30a) of the third nitride region 30 changes depending on the conditions of the carrier gas in the formation of the second nitride region 20, which is the foundation of the third nitride region 30.

When the carrier gas in the formation of the second nitride region 20 is hydrogen, the surface (first surface 30a) of the third nitride region 30 has large unevenness. When the carrier gas in the formation of the second nitride region 20 includes nitrogen, the unevenness of the surface (first surface 30a) of the third nitride region 30 is small.

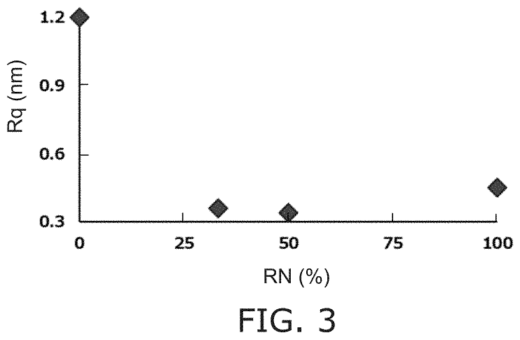

FIG. 3 is a graph view illustrating characteristics of the nitride semiconductor.

The horizontal axis of FIG. 3 is the ratio RN (volume ratio) of nitrogen in the carrier gas in the formation of the second nitride region 20. The vertical axis is the root mean square roughness Rq of the surface (first surface 30a) of the third nitride region 30. As shown in FIG. 3, when the ratio RN is 0% (when the carrier gas is hydrogen), the root mean square roughness Rq is large. As shown in FIG. 3, when the ratio RN is not less than 25%, the root mean square roughness Rq becomes remarkably small. When the ratio RN is 100%, the root mean square roughness Rq becomes slightly large.

It was found that the surface irregularities of the third nitride region 30 on the second nitride region 20 change depending on the conditions for forming the second nitride region 20. If the surface of the third nitride region 30 has large irregularities, it is difficult to obtain stable characteristics. For example, reliability tends to be low.

In the embodiment, the formation of the second nitride region 20 includes using a processing gas including a carrier gas including hydrogen and nitrogen (e.g., a third gas). The volume ratio of nitrogen in the third gas (that is, the ratio RN) is preferably not less than 20%. Thereby, for example, the root mean square roughness Rq can be reduced to, for example, not more than 0.4 nm. The volume ratio of nitrogen in the third gas (that is, the ratio RN) may be not less than 30% and not more than 50%. Thereby, for example, the root mean square roughness Rq can be made smaller, for example, to not more than 0.38 nm.

Hereinafter, an example of the characteristics of the semiconductor device based on the sample in which the carrier gas is changed in the formation of the second nitride region 20 will be described. The semiconductor device is a transistor as described later. In the transistor, a carrier region (for example, a two-dimensional electron gas) is formed in a portion of the first nitride region 10 facing the second nitride region 20. The first nitride region 10 corresponds to, for example, an electron traveling layer.

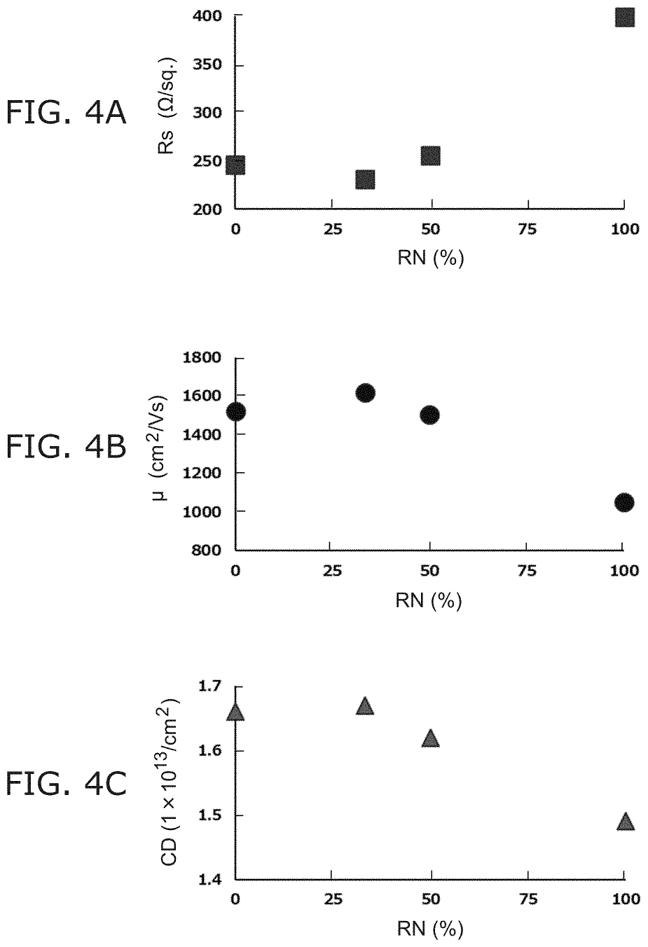

FIGS. 4A to 4C are graph views illustrating characteristics of the semiconductor device.

The horizontal axis of these figures is the ratio RN (volume ratio) of nitrogen in the carrier gas in the formation of the second nitride region 20. The vertical axis of FIG. 4A is the sheet resistance Rs of the first nitride region 10. The vertical axis of FIG. 4B is the mobility p. The vertical axis of FIG. 4C is the carrier density CD in the carrier region.

As shown in FIG. 4A, when the ratio RN of nitrogen in the carrier gas is 100%, the sheet resistance Rs is high. A low sheet resistance Rs is obtained when the ratio RN is 0% to 50%. A particularly low sheet resistance Rs is obtained when the ratio RN is 30%.

As shown in FIG. 4B, when the ratio RN of nitrogen in the carrier gas is 100%, the mobility μ is low. A high mobility μ is obtained when the ratio RN is 0% to 50%. A particularly high mobility μ is obtained when the ratio RN is 30%.

As shown in FIG. 4C, when the ratio RN of nitrogen in the carrier gas is 100%, the carrier density CD is low. A high carrier density CD is obtained when the ratio RN is 0% to 50%. A particularly high carrier density CD is obtained when the ratio RN is 30%.

On the other hand, as already described with respect to FIG. 3, when the ratio RN is 0%, the root mean square roughness Rq of the surface (first surface 30a) of the third nitride region 30 is large. From the above results, the ratio RN is preferably more than 0% and preferably not more than 50%. As a result, a small root mean square roughness Rq, a low sheet resistance Rs, a high mobility μ, and a high carrier density CD can be obtained.

As described above, when the ratio RN of nitrogen in the carrier gas in the formation of the second nitride region 20 exceeds 0%, a small root mean square Rq can be obtained, and stable characteristics can be easily obtained. The range of practical ratio RN is higher than 0%. On the other hand, in the practical range, when the ratio RN is 100%, the electrical characteristics (sheet resistance Rs, mobility μ, and carrier density CD) deteriorate. It is considered that this is because the state in the vicinity of the second nitride region 20 and its interface changes depending on the ratio RN. Hereinafter, an example of the result of HAADF-STEM (High Angle Annular Dark-Field Scanning Transmission Electron Microscopy) analysis of the nitride member 10M of the sample when the ratio RN is changed will be described.

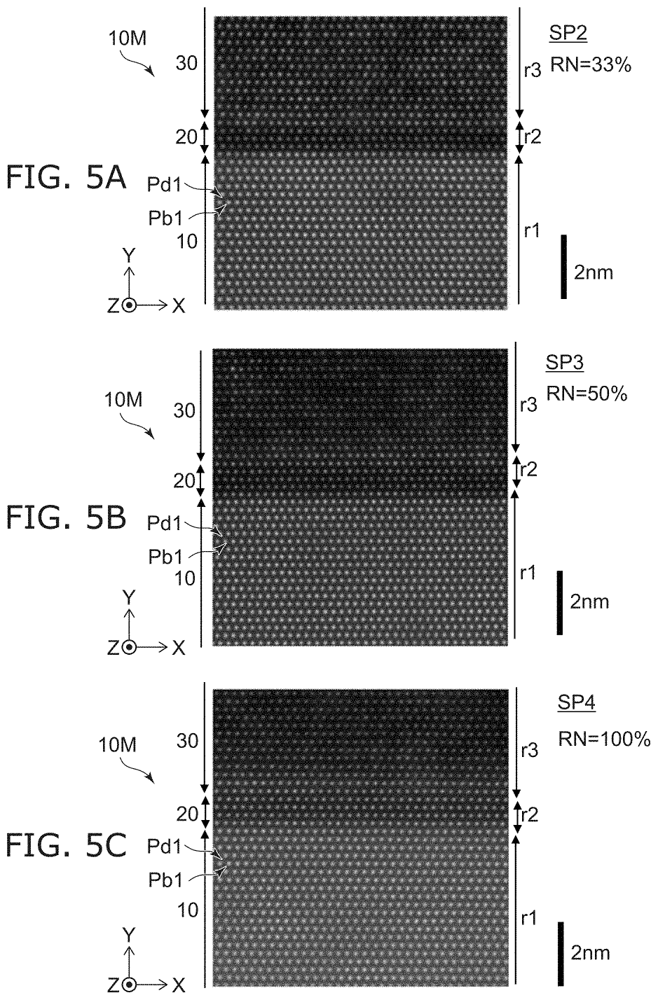

FIGS. 5A to 5C are HAADF-STEM images of the nitride semiconductor.

FIG. 5A corresponds to the second sample SP2. As described above, in the second sample SP2, the ratio RN of nitrogen in the carrier gas in the formation of the second nitride region 20 is 33%. FIG. 5B corresponds to the third sample SP3. In the third sample SP3, the ratio RN of nitrogen in the carrier gas in the formation of the second nitride region 20 is 50%. FIG. 5C corresponds to the fourth sample SP4. In the fourth sample SP4, the ratio RN of nitrogen in the carrier gas in the formation of the second nitride region 20 is 100%.

As shown in FIGS. 5A to 5C, in the HAADF-STEM image of the nitride member 10M, there are a first image region r1 corresponding to the first nitride region 10, a second nitride region 20 corresponding to the second nitride region 20, and a third image region r3 corresponding to the third nitride region 30. In these image regions, there is a difference in brightness depending on the difference in composition within the nitride member 10M. As shown in FIGS. 5A and 5B, in the second sample SP2 and the third sample SP3, the difference in brightness at the interface between these image regions is clear. On the other hand, as shown in FIG. 5C, in the fourth sample SP4, the difference in brightness at the interface between these image regions is unclear. It is considered that such a difference is related to the deterioration of the electrical characteristics (sheet resistance Rs, mobility μ, and carrier density CD) in the fourth sample SP4.

As shown in FIGS. 5A to 5C, the HAADF-STEM image includes multiple bright points Pb1 and a dark area Pd1. The dark area Pd1 is an area between multiple bright points Pb1. The brightness of the dark area Pd1 is lower than the brightness of the multiple bright points Pb1. The bright point Pb1 corresponds to the position of a Group III atom (Ga or Al). The dark area Pd1 corresponds to the area between Group III atoms.

In the first image region r1 corresponding to the first nitride region 10, the position of the bright point Pb1 corresponds to the position of Ga. In the second image region r2 corresponding to the second nitride region 20, the position of the bright point Pb1 corresponds to the position of Al. In the third image region r3 corresponding to the third nitride region 30, the position of the bright point Pb1 corresponds to the position of Al or In.

In the HAADF-STEM image, the bright point Pb1 (point corresponding to Al) in the second image region r2 is darker than the bright point Pb1 (point corresponding to Ga) in the first image region r1. It is considered that this is because the atomic weight of Al is smaller than the atomic weight of Ga. The brightness of the bright point Pb1 (the point corresponding to Al or In) in the third image region r3 depends on the composition ratio of In and Al.

As described above, in the HAADF-STEM image, the dark area Pd1 corresponds to the region between the Group III atoms. When the crystallinity is very high and the fluctuation of the position of the atom in the crystal is small, it is considered that the brightness of the dark area Pd1 is low and substantially independent of the type of Group III atom (Al, Ga or In). When the crystallinity is low, the brightness of the dark area Pd1 becomes brighter according to the crystallinity (fluctuation of the position of atoms). Therefore, when the crystallinity is low, the brightness of the dark area Pd1 is affected by the crystallinity and the atomic weight. The brightness of the dark area Pd1 can be an index corresponding to crystallinity.

In the following, an example of a change (distribution) of the average value of the brightness of the dark area Pd1 in the X-axis direction along the Z-axis direction will be described.

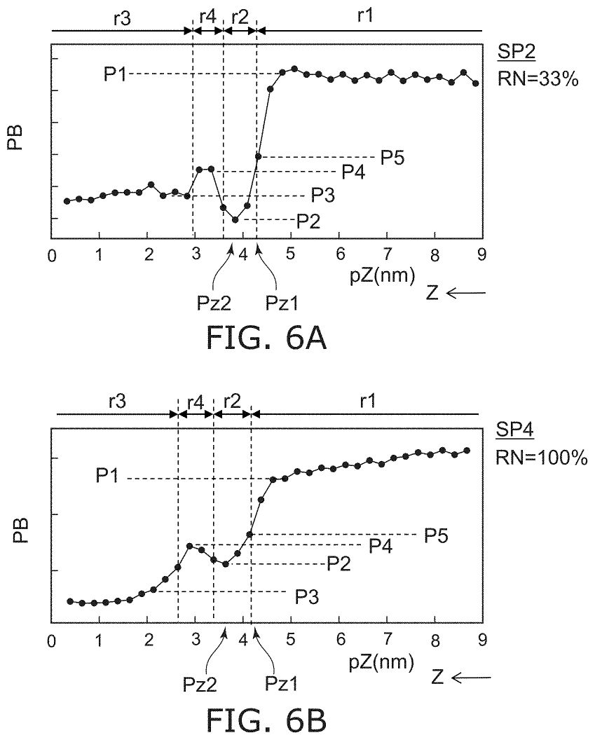

FIGS. 6A and 6B are graph views illustrating distributions of brightness in the HAADF-STEM image of the nitride semiconductor.

FIG. 6A corresponds to the second sample SP2. In the second sample SP2, the ratio RN of nitrogen in the carrier gas in the formation of the second nitride region 20 is 33%. FIG. 6B corresponds to the fourth sample SP4. In the fourth sample SP4, the ratio RN is 100%. The horizontal axis of these figures is the position pZ along the Z-axis direction. The vertical axis is the brightness PB (relative value) in the dark area Pd1 in the HAADF-STEM image.

As shown in FIG. 6A, in the second sample SP2 having a ratio RN of 33%, the brightness PB in the dark area Pd1 suddenly changes in the second image region r2 corresponding to the second nitride region 20. On the other hand, as shown in FIG. 6B, in the fourth sample SP4 having a ratio RN of 100%, the change in the brightness PB in the dark area Pd1 is not sudden. In the fourth sample SP4, the brightness PB in the dark area Pd1 of the second image region r2 corresponding to the second nitride region 20 is not sufficiently low.

For example, as shown in FIG. 6A, the third brightness P3 of the dark area Pd1 in the third image region r3 corresponding to the third nitride region 30 is lower than the first brightness P1 of the dark area Pd1 in the image region rl corresponding to the first nitride region 10. The second brightness P2 of the dark area Pd1 in the second image region r2 corresponding to the second nitride region 20 is lower than the third brightness P3.

The third nitride region 30 includes Al and In as Group III elements. On the other hand, the first nitride region 20 includes Ga as a group III element. In general, as the number of types of elements increases, the crystallinity (fluctuation of the position of the element) tends to increase. In the embodiment, the third brightness P3 is lower than the first brightness P1. This corresponds to the high crystallinity of both the first nitride region 10 and the third nitride region 30.

In the embodiment, the second brightness P2 in the second nitride region 20 including an element having a small atomic weight is lower than the third brightness P3. This corresponds to a sufficiently high crystallinity of the second nitride region 20. For example, the diffusion of elements from other regions to the second crystal region 20 is suppressed. Since the crystallinity is sufficiently high in the second nitride region 20, the image is not blurred and the brightness of the image is low. The profile illustrated in FIG. 6A is obtained when the composition changes sharply between the first nitride region 10 and the second nitride region 20 while maintaining high crystallinity. In such a case, high electrical characteristics can be obtained.

On the other hand, in the fourth sample SP4 illustrated in FIG. 6B, the second brightness P2 is higher than the third brightness P3. This corresponds to the low crystallinity of the second nitride region 20. In such cases, the electrical characteristics are low.

As shown in FIG. 6A, in the HAADF-STEM image, the fourth brightness P4 of the dark area Pd1 in the fourth image region r4 between the second image region r2 and the third image region r3 is between the first brightness P1 and the third brightness P3. The fourth image region r4 corresponds to the region between the second nitride region 20 and the third nitride region 30. It is considered that the high fourth brightness P4 corresponds to the segregation of the element (for example, In) included in the third nitride region 30 in the region between the second nitride region 20 and the third nitride region 30. For example, it is considered that the composition change from the second nitride region 20 of AlN to the third nitride region 30 of AlInN is not gradual, and the composition changes steeply to the extent that In segregates. The fact that the second brightness P2 of the dark area Pd1 is sufficiently low in the second image region r2 as compared with the fourth image region r4 corresponds to the fact that the crystallinity of the second nitride region 20 is sufficiently high.

As shown in FIG. 6A, in the HAADF-STEM image, the dark area Pd1 at the interface position Pz1 between the first nitride region 10 and the second nitride region 20 has a fifth brightness P5.

The second brightness P2 is the minimum value of the brightness PB in the dark area Pd1 in the second image region r1. The second nitride region 20 has a minimum value position Pz2 corresponding to this minimum value (second brightness P2).

The ratio of the distance between the interface position Pz1 and the minimum value position Pz2 along the first direction (Z-axis direction) to the thickness t2 of the second nitride region 20 along the first direction is taken as a first ratio. In the example of FIG. 6A, the distance between the interface position Pz1 and the minimum value position Pz2 along the first direction (Z-axis direction) is 0.5 nm. The thickness t2 is 1 nm. The first ratio is 0.5.

The ratio of the difference between the first brightness P1 and the second brightness P2 to the difference between the first brightness P1 and the third brightness P3 is taken as a second ratio. In the example of FIG. 6A, the second ratio is 1.2.

In the embodiment, a third ratio of the first ratio to the second ratio is preferably not less than 1. The third ratio corresponds to the rate of change of the brightness PB in the region including the interface position Pz1 between the first nitride region 10 and the second nitride region 20. When the third ratio is high, it changes steeply with respect to the change in the first direction (Z-axis direction). In the example of FIG. 6A, the third ratio is 2.4.

In the example of FIG. 6B, the first ratio is about 0.6 and the second ratio is 0.78. Therefore, the third ratio is 1.3.

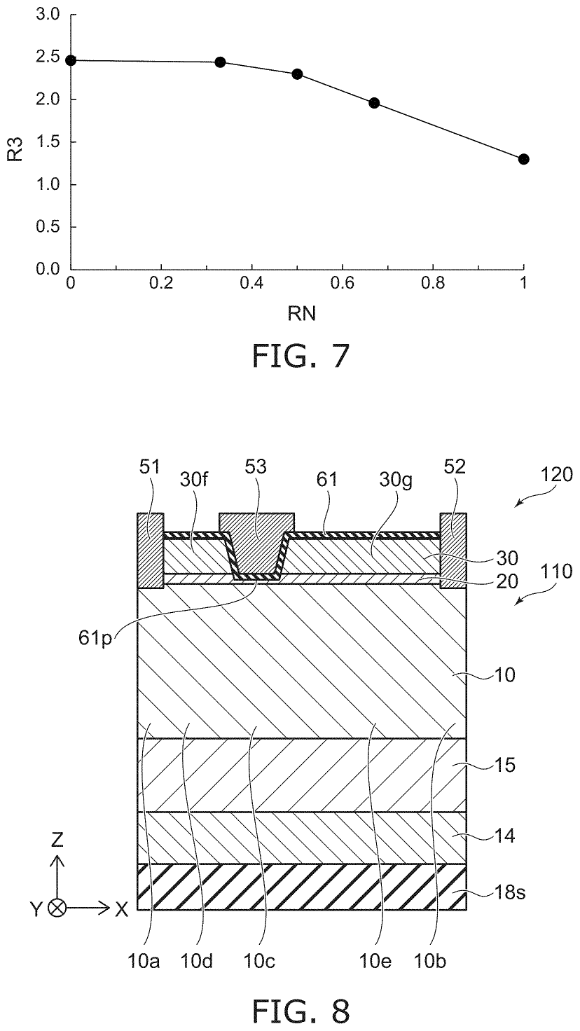

FIG. 7 is a graph view illustrating characteristics of the semiconductor device.

The horizontal axis of FIG. 7 is the ratio RN (volume ratio) of nitrogen in the carrier gas in the formation of the second nitride region 20. The vertical axis is the third ratio R3. As shown in FIG. 7, as the ratio RN increases, the third ratio R3 decreases. As described above, high electrical characteristics are obtained when the ratio RN is 0% to 50%. From FIG. 7, the third ratio R3 is preferably not less than 2. High electrical characteristics are obtained when the steep change in composition of the nitride member 10M is steep. In the embodiment, the third ratio R3 is more preferably not less than 2. High electrical characteristics can be stably obtained.

### Second Embodiment

The second embodiment relates to a semiconductor device.

FIG. 8 is a schematic cross-sectional view illustrating a semiconductor device according to a second embodiment.

As shown in FIG. 8, a semiconductor device 120 according to the embodiment includes the nitride semiconductor 110 according to the first embodiment, a first electrode 51, a second electrode 52, a third electrode 53, and an insulating member 61.

The direction from the first electrode 51 toward the second electrode 52 is along a second direction crossing the first direction. The second direction is, for example, the X-axis direction. The position of the third electrode 53 in the second direction is between the position of the first electrode 51 in the second direction and the position of the second electrode 52 in the second direction.

The first nitride region 10 includes, for example, a first partial region 10a, a second partial region 10b, a third partial region 10c, a fourth partial region 10d, and a fifth partial region 10e. The direction from the first partial region 10a toward the first electrode 51 is along the first direction (Z-axis direction). The direction from the second partial region 10b toward the second electrode 52 is along the first direction. The third partial region 10c is between the first partial region 10a and the second partial region 10b in the second direction (for example, the X-axis direction). The direction from the third partial region 10c toward the third electrode 53 is along the first direction. The fourth partial region 10d is between the first partial region 10a and the third partial region 10c in the second direction. The fifth partial region 10e is between the third partial region 10c and the second partial region 10b in the second direction.

The third nitride region 30 includes a sixth partial region 30f and a seventh partial region 30g. The direction from the fourth partial region 10d toward the sixth partial region 30f is along the first direction (Z-axis direction). The direction from the fifth partial region 10e toward the seventh partial region 30g is along the first direction.

The insulating member 61 includes a first insulating region 61p. The first insulating region 61p is provided between the third partial region 10c and the third electrode 53 in the first direction (Z-axis direction).

In the semiconductor device 120, a current flowing between the first electrode 51 and the second electrode 52 can be controlled by a potential of the third electrode 53. The potential of the third electrode 53 is, for example, a potential with reference to a potential of the first electrode 51. The first electrode 51 is, for example, a source electrode. The second electrode 52 is, for example, a drain electrode. The third electrode 53 is, for example, a gate electrode. The semiconductor device 120 is, for example, HEMT (High Electron Mobility Transistor). In the embodiment, a semiconductor device which is possible to improve the characteristics can be provided.

### Third Embodiment

Third embodiment relates to a method for manufacturing the nitride semiconductor.

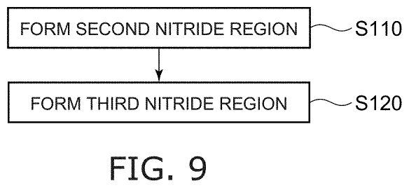

FIG. 9 is a flow chart illustrating a method for manufacturing the nitride semiconductor according to a third embodiment.

As shown in FIG. 9, the method for manufacturing the nitride semiconductor according to the embodiment includes forming the second nitride region 20 (step S110) and forming the third nitride region 30 (step S120).

In step S110, the second nitride region 20 including Alₓ₂Ga₁₋ₓ₂N (0<x2≤1, x1<x2) is formed on the first nitride region 10 including Alₓ₁Ga₁₋ₓ₁N (0≤x1<1). In step S120, the third nitride region 30 including Alₓ₃In₁₋ₓ₃N (0<x3<1, x3<x2) or Al_{y3}Ga_{1-y3}N (0<y3<1, x1<y3<x2) is formed on the second nitride region 20.

The second nitride region 20 is formed by using a processing gas including a first gas including Al, a second gas including ammonia, and a third gas including hydrogen and nitrogen. The volume ratio (ratio RN) of nitrogen in the third gas is not less than 20% and not more than 50%. As a result, a small root mean square roughness Rq, a low sheet resistance Rs, a high mobility μ, and a high carrier density CD can be obtained. The volume ratio (ratio RN) may be not less than 30% and not more than 50%.

In the HAADF-STEM image of the nitride member 10M including the first nitride region 10, the second nitride region 20, and the third nitride region 30, the third brightness P3 of the third image region r3 corresponding to the third nitride region 30 is between the first brightness P1 of the first image region r1 corresponding to the first nitride region 10 and the second brightness P2 of the second image region r2 corresponding to the second nitride region 20.

For example, the first nitride region 10 includes GaN. The second nitride region 20 includes AlN. The third nitride region 30 includes AlInN.

The third nitride region 30 includes the first surface 30a and the second surface 30b. The second surface 30b faces the second nitride region 20. In the first direction (Z-axis direction) from the first nitride region 10 toward the second nitride region 20, the second surface 30b is between the second nitride region 20 and the first surface 30a. The root mean square roughness Rq of the first surface 30a is, for example, not more than 0.6 nm.

According to the embodiment, it is possible to provide a nitride semiconductor, a wafer, a semiconductor device, and a method for manufacturing the nitride semiconductor, which is possible to improve the characteristics.

In the specification, “a state of electrically connected” includes a state in which multiple conductors physically contact and a current flows between the multiple conductors. “a state of electrically connected” includes a state in which another conductor is inserted between the multiple conductors and a current flows between the multiple conductors.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in nitride semiconductors such as nitride regions, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all nitride semiconductors, wafers, semiconductor devices, and methods for manufacturing nitride semiconductors practicable by an appropriate design modification by one skilled in the art based on the nitride semiconductors, the wafers, the semiconductor devices, and the methods for manufacturing nitride semiconductors described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nitride semiconductor, comprising:
a nitride member including a first nitride region, a second nitride region, and a third nitride region,
the second nitride region being between the first nitride region and the third nitride region in a first direction,
the first nitride region including Alₓ₁Ga₁₋ₓ₁N (0≤x1<1),
the second nitride region including Alₓ₂Ga₁₋ₓ₂N (0<x2≤1, x1<x2),
the third nitride region including Alₓ₃In₁₋ₓ₃N (0<x3<1, x3<x2) or Al_{y3}Ga_{1-y3}N (0<y3<1, x1<y3<x2),
a HAADF-STEM (High Angle Annular Dark-Field Scanning Transmission Electron Microscopy) of the nitride member including a plurality of bright points and a dark area between the bright points, the dark area being darker than the bright points, and
a third brightness of the dark area in a third image region corresponding to the third nitride region being lower than a first brightness of the dark area in a first image region corresponding to the first nitride region, a second brightness of the dark area in a second image region corresponding to the second nitride region being lower than the third brightness.

2. The semiconductor according to claim 1, wherein
in the HAADF-STEM image, a fourth brightness of the dark area in a fourth image region between the second image region and the third image region is between the first brightness and the third brightness.

3. The semiconductor according to claim 1, wherein
in the HAADF-STEM image, the dark area at an interface position between the first nitride region and the second nitride region has a fifth brightness,
the second brightness is a minimum value of brightness in the dark area in the second image region,
the second nitride region has a minimum value position corresponding to the minimum value,
a ratio of a distance along the first direction between the interface position and the minimum value position to a first thickness along the first direction of the second nitride region is a first ratio,
a ratio of an absolute value of a difference between the first brightness and the second brightness to an absolute value of a difference between the first brightness and the third brightness is a second ratio, and
a third ratio of the first ratio to the second ratio is not less than 1.

4. The semiconductor according to claim 1, wherein
the first nitride region includes GaN,
the second nitride region includes AIN, and
the third nitride region includes AlInN.

5. The semiconductor according to claim 4, wherein
a composition ratio in the third nitride region is not less than 0.15 and not more than 0.2.

6. The semiconductor according to claim 1, wherein
a thickness along the first direction of the second nitride region is not less than 0.5 nm and not more than 1.5 nm.

7. The semiconductor according to claim 1, wherein
the third nitride region includes a first surface and a second surface, the second surface faces the second nitride region, and the second surface is between the second nitride region and the first surface in the first direction, and
a root mean square roughness of the first surface is not more than 0.6 nm.

8. A wafer, comprising:
the semiconductor according to claim 1; and
a substrate,
the second nitride region being between the substrate and the third nitride region, and
the first nitride region being between the substrate and the second nitride region.

9. The wafer according to claim 8, wherein
the substrate includes silicon.

10. The wafer according to claim 8, wherein
the nitride member further includes
a fourth nitride region including AlN, and
a fifth nitride region including AlGaN,
the fifth nitride region is between the substrate and the first nitride region, and
the fourth nitride region is between the substrate and the fifth nitride region.

11. A semiconductor device, further comprising:
the semiconductor according to claim 1;
a first electrode;
a second electrode;
a third electrode; and
an insulating member,
a direction from the first electrode toward the second electrode being along a second direction crossing the first direction,
a position in the second direction of the third electrode being between a position in the second direction of the first electrode and a position in the second direction of the second electrode,
the first nitride region including a first partial region, a second partial region, a third partial region, a fourth partial region, and a fifth partial region,
a direction from the first partial region toward the first electrode being along the first direction,
a direction from the second partial region toward the second electrode being along the first direction,
the third partial region being between the first partial region and the second partial region in the second direction, and a direction from the third partial region toward the third electrode being along the first direction,
the fourth partial region being between the first partial region and the third partial region in the second direction,
the fifth partial region being between the third partial region and the second partial region in the second direction,
the third nitride region including a sixth partial region and a seventh partial region,
a direction from the fourth partial region toward the sixth partial region being along the first direction, a direction from the fifth partial region toward the seventh partial region being along the first direction, and
the insulating member including a first insulating region provided between the third partial region and the third electrode in the first direction.

12. A method for manufacturing a nitride semiconductor, comprising:
forming a second nitride region including Alₓ₂Ga₁₋ₓ₂N (0<x2≤1, x1<x2) on a first nitride region including Alₓ₁Ga₁₋ₓ₁N (0≤x1<1); and
forming a third nitride region including Alₓ₃In₁₋ₓ₃N (0<x3<1, x3<x2) or Al_{y3}Ga_{1-y3}N (0<y3<1, x1<y3<x2) on the second nitride region,
the forming the second nitride region including forming the second nitride region by using a processing gas including a first gas including Al, a second gas including ammonia, and a third gas including hydrogen and nitrogen, and
a volume ratio of the nitrogen in the third gas being not less than 20% and not more than 50%.

13. The method according to claim 12, wherein
in a HAADF-STEM (High Angle Annular Dark-Field Scanning Transmission Electron Microscopy) of the nitride member including the first nitride region, the second nitride region, and the third nitride region, a third brightness of a third image region corresponding to the third nitride region is between a first brightness of a first image region corresponding to the first nitride region and a second brightness of a second image region corresponding to the second nitride region.

14. The method according to claim 13, wherein
the first nitride region includes GaN,
the second nitride region includes AlN, and
the third nitride region includes AlInN.

15. The method according to claim 13, wherein
the third nitride region includes a first surface and a second surface, the second surface faces the second nitride region, the second surface is between the second nitride region and the first surface in a first direction from the first nitride region toward the second nitride region, and
a root mean square roughness of the first surface is not more than 0.6 nm.
